(19) United States
(12) Patent Application Publication
(10) Pub. No.: US 2010/0182021 A1
(43) Pub. Date: Jul. 22, 2010

(54) DETERMINATION OF THE SAFETY OF FOODSTUFFS FOR CONSUMPTION

(76) Inventor: Michaeal G. Singer, Harrisville, MI (US)

Correspondence Address: WEINER & BURT, P.C., 635 N US-23, POB 186, HARRISVILLE, MI, 48740, US

(21) Appl. No.: 12/600,267

(22) PCT Filed: May 23, 2008
(86) PCT No.: PCT/US2008/064696

§ 371 Date: Nov. 15, 2009

Related U.S. Application Data
(63) Continuation of application No. 11/912,887, filed on Oct. 27, 2007.
(60) Provisional application No. 60/939,703, filed on May 23, 2007.
(60) Provisional application No. 60/826,774, filed on Sep. 25, 2006.
(60) Provisional application No. 60/827,698, filed on Sep. 30, 2006.

(30) Foreign Application Priority Data
Mar. 18, 2006 (US) 11/386016
Oct. 10, 2006 (US) 11/548 003

(51) Int. Cl. G01R 27/08

(52) U.S. Cl. 324/692

(57) ABSTRACT

A method of determining and monitoring the safety of a foodstuff by subjecting the foodstuff to bioelectrical impedance analysis including measurement and calculation of values of resistance, reactance, impedance, capacitance, and phase angle of the foodstuff, and then tracking the values over time to illustrate freshness, palatability and safety of the foodstuff, and ascertaining difference in rate of change from established averages of freshness and palatability to show possible contamination of the foodstuff.

### CROSS-REFERENCE TO RELATED APPLICATIONS

The present application claims priority from and is a CIP of U.S. Provisional Application 60/939,703 filed May 23, 2007 and U.S. application Ser. No. 11/912,887 filed Oct. 27, 2007, the entire contents of which applications are incorporated herein by reference thereto. U.S. Provisional Application 60/939,703 claims priority from and is a CIP of U.S. application Ser. No. 11/548,003 filed Oct. 10, 2006 the complete disclosure of which is incorporated herein by reference thereto. U.S. application Ser. No. 11/912,887 is a National Phase filing of International Application PCT/US2007/005164 filed Feb. 28, 2007 which claims priority from and is a CIP of of U.S. application Ser. No. 60/827,698 filed Sep. 30, 2006, U.S. application Ser. No. 60/826,774 filed Sep. 25, 2006, U.S. application Ser. No. 11/386,016 filed Mar. 18, 2006, and U.S. application Ser. No. 11/548,003 filed Oct. 10, 2006, which in turn claims priority from and is a CIP of U.S. application Ser. No. 60/594,200 filed Mar. 18, 2005, which in turn claims priority of and is a CIP of U.S. application Ser. No. 10/701,004 filed Nov. 4, 2003 (now U.S. Pat. No. 7,003,346), which in turn claims priority from and is CIP of U.S. application Ser. No. 60/424,828 filed Nov. 8, 2002, which in turn is a CIP of U.S. application Ser. No. 09/848,242 filed Mar. 3, 2001 (now U.S. Pat. No. 6,587,715).

### BACKGROUND OF THE INVENTION

The present invention relates generally to a method and system of determining the safety for consumption of a foodstuff biological entity including at least a portion of a live or previously-live organism.

After safety (which is often assumed), consumers believe palatability to be the single most important component of meat and foodstuff quality. Contamination of foodstuff has become a significant threat to public health.

Whether the source of the contamination is infection or pollutant, a cumulative threshold of effect is attained which results in morbidity and mortality to the consuming entity. A common aspect of the effects of these contaminants is the impact upon the cellular architecture, especially the membrane, of the biological foodstuff:

Live and previously-live foodstuffs have in common a basic cellular structure that applicant has previously demonstrated relates to freshness and palatability.

The prior, but not necessarily relevant, art is exemplified in the following U.S. patents and patent applications.

U.S. Pat. No. 4,985,125, issued in 1991, to Watanabe, et al; entitled; “Method for Detecting Meat Freshness Using a Biosensor”, in which is described; “A biosensor comprising a main body and a built-in sensing electrode provided therein, wherein said sensing electrode is provided with a sensing part to which a buffer solution can be constantly fed and said main body is provided with an inlet which is brought into direct contact with a specimen to thereby incorporate the molecule to be assayed from said specimen there through, said inlet being covered with a membrane through which the molecule to be assayed can permeate. This biosensor enables a specified molecule contained in a specimen to be rapidly and conveniently assayed without requiring any pretreatment of the specimen.”

U.S. Pat. No. 5,088,822, issued in 1992 to Kanda, entitled; “Meat Freshness Measuring Apparatus”, in which is described; “A meat freshness measuring apparatus measures the freshness of meat by detecting changes in a pigment contained in the meat. For this purpose, the meat is exposed to rays of light of different wavelengths applied from a light source, and the rays obtained from the meat are separated into spectra for the respective wavelengths, which are received by a photoelectric conversion element. Spectrum data for each wavelength are amplified and then the amplified data are converted to a digital signal by an A/D converter, whereby the digital signal is stored in a RAM. Based on the stored spectrum data and using a prescribed equation of calculation, a content of the pigment in the meat is calculated and outputted by a CPU.

U.S. Pat. No. 5,788,643, issued in 1998 to Feldman entitled “Process for Monitoring Patients with Chronic Congestive Heart Failure”, in which is described “In a process for monitoring patients with chronic congestive heart failure, a high frequency current is passed between electrodes applied to two limbs of a patient. The current, voltage and phase angle between the measured current and voltage are measured to enable the calculation of congestive heart failure (CHF) indicia values. The calculated CHF indicia values are then compared with baseline values established when the patient is in a known, stable condition. Intervention is initiated if the differences between the calculated CHF indicia values and the baseline values are outside of established tolerances. The CHF indicia values may include resistance, reactance, impedance, total body water and extracellular water. Moreover, the CHF indicia values may include a figure of merit indicative of the hydration status of the patient.

U. S. Published Patent Application 2004/0014235, published in 2004 by Kelly, et al, entitled “Polymeric Food Spoilage Sensor”, in which is described, “A polymeric food spoilage sensor comprises a polymer containing a polyazamacrocyclic transition metal complex. The complex selectively binds biogenic amines, such as cadaverine, putrescine and histamine, which are released by food spoilage microorganisms. The polymer undergoes a detectable color change upon exposure to biogenic amine, thus indicating that food spoilage has probably occurred. In one embodiment, the polymer is molecularly imprinted with the biogenic amine to impart selective binding affinity. The polymer is easily incorporated in common food containers and can be employed in fiber optic detection devices.”

U. S. Published Patent Application 2005/0058751, published in 2005 by Brotsky et al., entitled; “Yield and Shelf Life for Meats”, in which is described an; “The invention is directed to a process for treating meat to achieve higher yield, without negatively affecting the appearance of the meat. The process comprises the steps of 1) treating the meat, preferably by injection, with a higher pH phosphate solution having a pH of above pH 6.0 and 2) after treating the meat with the higher pH phosphate solution, contacting the meat, preferably by dipping or spraying, with a lower pH solution of preferably less than about pH 5.6.”

The achieved goal of the present invention is to avoid the disadvantages and deficiencies of conventional methods and techniques, and to provide a novel method for determination of the safety for consumption of foodstuffs.

### SUMMARY OF THE INVENTION

The term ‘live’ foodstuffs as used herein means any and all living organisms to include; meats, fish, fowl, fruits and vegetables.

The term ‘biological entity’ as used herein means any and all portions, parts or whole of a live or previously-live organism.

The term ‘subject’ as used herein means that portion, segment, ‘cut’ or whole biological entity studied.

The term ‘electrode scheme’ as used herein means any and all configurations utilized to introduce and measure the electrical signal and corresponding voltage drop by placement on the subject's surface, around said surface, into said subject and/or through placing said subject onto the electrode configuration singularly or as part of another appliance.

The term ‘average’ as used herein means the product of the statistically valid sample size number divided into the measured values.

The term ‘normal’ as used herein means the product of the average peculiar to and comprised of but not limited to a defined group; age, gender, species, or cut.

The term ‘optimal’ as used herein means the best or most favorable value; which may be obtained subjectively individually or collectively or it may be obtained objectively as compared to a ‘criterion’ or ‘gold-standard’ designated and agreed upon by professional, experts and those ‘experienced’ in the field of endeavor and by personal selection of a value on that objective scale an individual may express and select their personal optimal value.

The term ‘individual’ as used herein means those findings peculiar to a single subject or to a uniformly collective group of individual subject's assigned to a group based upon a preponderance of similar and agreed upon characteristics such as but not limited to; genus, species, cut, breed, or other such recognized characters of physicality and composition.

The term ‘meat’ as used herein means bovine (Bos), porcine, lamb (Ovis Aries), buffalo, bison camel, goat (Capra Hircus) equine, donkey, llama, reindeer and yak.

The terms ‘fowl’ or ‘poultry’ as used herein means; chicken, turkey, duck, geese, guinea fowl and swan.

The term ‘external appliance’ as used herein is comprised of but not limited to scales, refrigerators, display, and/or packaging materials, methods, device or systems and portable temperature controlled appliances, and cooking appliances.

The term ‘Consumption Safety Index’ as used herein are the objective results scaled to the characteristics of the foodstuff relating to safe versus unsafe.

The present invention provides a method of determining and monitoring the safety of a foodstuff biological entity including at least a portion of a live or previously-live organism, comprising the steps of:

subjecting said foodstuff biological entity to bioelectrical impedance analysis including measurement and/or calculation of values of resistance, reactance, impedance, capacitance, and/or phase angle of said foodstuff biological entity.

tracking said values over time to illustrate freshness, palatability and safety of said foodstuff biological entity; and

ascertaining difference in rate of change from established averages of freshness and palatability which is indicative of contamination of said foodstuff biological entity.

The present invention also provides a method and system of determining safety for consumption of a foodstuff biological entity including at least a portion of a live or previously-live organism, comprising the steps of:

subjecting said foodstuff biological entity to bioelectrical impedance analysis for measurement and composition analysis; and

utilizing results of said subjecting step to illustrate an objective scale of safety of said biological entity.

The present invention further provides a method for determining safety for consumption of a foodstuff biological entity, grossly in terms of safe or not safe, and then more precisely as related to juiciness, tenderness and flavor, changes of consumption safety of said biological entity, and/or timing of optimal consumption safety, loss of consumption safety of said biological entity and/or illustrating an objective scale of consumption safety to alert a producer, purveyor, merchant and/or consumer, comprising the steps of:

providing normal, average, optimal and individual measured values of resistance, reactance, capacitance and phase angle, of the sample subject studied of the biological entity;

measuring initial values of resistance, reactance, capacitance and phase angle, of the sample subject biological entity;

taking measurements of resistance, reactance, capacitance and phase angle, at predetermined intervals of time based upon the characteristics and proposed utilization of the individual subject;

recording said measurements; comparing initial values of said measurements to normal values of said measurements and to serially measure values of said measurements; and

determining, from said comparison steps, hallmarks of consumption safety of said biological entity, said progression and rate of changes in consumption safety to a zenith, nadir or loss of the consumption safety of said biological entity, to a specific individual ‘Consumption Safety Index’ value which may be reported and found as the inherent average, normal, optimal and/or individual characteristics of said biological entity or portion thereof.

An object of the present invention is the extension of knowledge of food safety and freshness based upon expanding the data collection methodologies to more clearly illustrate the relationship of the biological system to its environment as relates to the time-span rate of cellular degradation.

Other objects, advantages, and features of the present invention will become apparent to those persons skilled in this particular area of technology and to other persons after having been exposed to the present patent application.

### DETAILED DESCRIPTION OF THE INVENTION

The present application is a continuation-in-part of U.S. patent application Ser. No. 11/548,003 and International Patent Application PCT/US2007/005164, the entire contents of which applications are incorporated herein by reference thereto.

Contamination of foodstuff has become a significant threat to public health. Whether the source of the contamination is infection or pollutant, a cumulative threshold of effect is attained which results in morbidity and mortality to the consuming entity.

A common aspect of the effects of these contaminants is the impact upon the cellular architecture, especially the membrane, of the biological foodstuff. Live and previously-live foodstuffs have in common a basic cellular structure which applicant has previously demonstrated relates to freshness and palatability.

The present invention is based upon the electrical illustration of that cellular level of physiology (pathophysiology) through impedance analysis in which applicant utilizes the measured electrical values of impedance, resistance, and reactance and calculate phase angle and capacitance and track them over time to illustrate freshness and palatability.

The measurement of the impedance may be done at various frequencies, power levels, constant current strengths and electrode configurations with the resultant basis of establishing a ‘normal’ value and tracking episodically and/or serially the changes associated with freshness, palatability and safety of the foodstuff.

In the present invention, it is specifically the difference in the rate of change from established averages of freshness and palatability which are indicative of contamination from any source as the level of the contamination reaches a zenith through in the case of a biological (bacterial) its colony count or in that of a pollutant its accumulated concentration is so great as to adversely impact the cellular architecture (process and membranes) as evidenced by an increased rate of change of the measured electrical values greater than that associated with changes of freshness and palatability.

As the rate of change accelerates from its normal pace, it is indicative of an adverse condition for the foodstuff consumer which may warrant further testing or simply the disposal of the foodstuff.

Thus, the present invention provides a method and system to obtain and use the measured values and products of bioelectrical impedance analysis (BIA) as an objective means to equivalently illustrate electrically, various physiological characteristics, and upon which characterization the safety of foodstuffs for consumption can be objectively described and compared and practically utilized.

The method of BIA measurement may comprise various configurations so as to accommodate the diversity of foodstuffs so measured to the extent that the interface with the foodstuff (electrode array/scheme, electrical power management (frequencies, current and voltages)) and circuit models (series and/or parallel) may be varied as such to incorporate the subject foodstuff within the controlled electrical circuit or field of the BIA measurement comprised in such manner as to complete said measurement.

The interfaces for electrode array/scheme may be comprised of placement of the studied foodstuff within a generated electrical field array, on an electrode scheme array, placing the electrode array about around or as comprised in such configuration as to measure ‘capture’, characterize and illustrate the unique geometry and traits of the subject foodstuff in its entirety or as possible the electrode scheme and array may be introduced directly into the study subject foodstuff, and/or that such electrical power management configurations may be comprised of fixed or variable frequencies, currents and voltages and circuit models (series and/or parallel) and that the measured and calculated values be comprised of such values and sampling rates to adequately capture, characterize and illustrate the unique geometry and traits of the subject foodstuff in its entirety.

The electrical signals utilized to measure and calculate the impedance, resistance, reactance, capacitance and phase angle may be comprised of multiple schemes based upon the type and geometry of the foodstuff; a mono or singular frequency, multiple frequencies, or a spectroscopic illustration across a segment or band of frequencies.

The measured and calculated electrical values comprised of impedance, resistance, reactance, capacitance and phase angle are related to the comprised physiological values of fluid; volume and distribution, the cell mass; volume, character and membrane vitality as related to the unique and inherent characteristics palatability (flavor, juiciness and tenderness) of the studied subject foodstuff and reported in such a manner as to provide a basis for objective assessments and subjective interpretation of said comprised values for foodstuff product; safety grading, pricing, handling, management and disposition.

Thus, the present invention provides a method and system for the use of bioelectrical impedance analysis (BIA) in the electrical measurement of a biological equivalent model of ‘live’ foodstuffs or ‘biological entities’ to provide an objective assessment and scale of safety and freshness as related to the characteristics, volume and distribution of fluids, tissues and cells as well as the electrical vitality of cells and cell membranes through the measurement of impedance (Z), resistance (R), reactance (Xc), capacitance (Cp) and the calculation of phase angle (Pa) at a fixed or variable electrical frequency, current and voltage through a tetrapolar electrode scheme placed on, around and/or in or with the subject placed upon the array or by placing the study subject within a electrical field or a portion thereof by placing said foodstuff biological entity or a portion thereof onto an electrode configuration singularly or as comprised as part of an external appliance; such as part of a scale; refrigerator or a portable temperature controlling device, packaging or display, the study subject as measured individually; compared to normal, average and optimal values and as tracked serially over time and compared to changes from the initial measurement.

More specifically the present invention provides a method and system for determining the palatability of a portion or whole live or previously live foodstuff such as a meat, fish, fowl, fruit or vegetable, to grade its characteristics (consumption safety), quality and salability, and to support decisions regarding its disposition, preparation and presentation and cost and consumption.

The methods of the present invention can utilize a modification of the body composition analyzer disclosed in U.S. Pat. No. 5,372,141, the entire contents of which are incorporated herein by reference thereto. Such modification may include, but not be limited to, impedance measuring instrumentation capable of measuring impedance, resistance and reactance for the calculation of capacitance and phase angle from selected singular or mono-frequency, multiple frequencies and/or impedance spectroscopic analysis or changes in current, power and voltage.

In accordance with the present invention, utilization of BIA in a biological model provides an objective assessment of the study subject's (whole or section of the biological entity) volume and distribution of fluids, tissues and cells, as well as the electrical health and vitality of the cells and membranes.

The characteristics of BIA include precision, accuracy, feasibility and economy. BIA may be applied to any subject whole or an area of representative sample or interest to be studied and examined for safety for consumption; a section thereof, regionally, or to the whole biological entity. It is non-offensive, causing no harm. It may be repeated freely, as desired to capture various dynamic changes unique to the variety of live foodstuffs (biological entities), to illustrate initial values and change over time so that progression of conditions can be monitored and changes that affect consumption safety determined. The specific value of BIA is in its precision of measurement and the significance of the electrically measured products illustration of the biological foodstuff entities equivalent physiological variables of fluid, tissue and cells volume and distribution, cell membrane volume and vitality, derivative values initially and comparison to average, optimal, normal, and subsequent individual values and changes serially over time.

Based upon the individual genus, type; species, ‘cut’ or sample of the biological foodstuff entity, palatability is determined by the baseline values, and changes thereto (rate, zenith and nadir) of the measured and calculated values initially and over time. The properties of the electrical values directly relate to biological equivalents such as; measured R is inverse to water content (juiciness) so an increasing R value is indicative of water loss and a decreasing R value is indicative of water accumulation as well as measured Xc is proportional to cell mass so a decreased Xc is indicative of cell membrane loss through such processes (naturally occurring or artificially induced) as fragmentation or proteolysis; a diminution of the Xc value and/or a change in the rate of said diminution from a zenith towards a nadir is indicative of optimal safety for consumption which may progress beyond that nadir of safety and become non-safe.

Comparison of the Xc value of one sample of the same genus and species, section and cut of a biological entity to another sample of the same genus and species, section and cut of a biological entity illustrates a comparative scale of consumption safety.

There have been described hereinabove several of the unique and novel embodiments of the present invention which can be practiced and constructed in many different ways and configurations.

It should be understood that many changes, modifications, variations, and other uses and applications will become apparent to those persons skilled in this particular area of technology and to others after having been exposed to the present patent application.

Any and all such changes, modifications, variations and other uses and applications which do not depart from the spirit and scope of the present invention are therefore covered by and embraced within the present invention and the patent claims set forth hereinbelow.

1. A method of determining and monitoring the safety of a foodstuff biological entity including at least a portion of a live or previously-live organism, comprising the steps of:
subjecting said foodstuff biological entity to bioelectrical impedance analysis including measurement and/or calculation of values of resistance, reactance, impedance, capacitance, and/or phase angle of said foodstuff biological entity.
tracking said values over time to illustrate freshness, palatability and safety of said foodstuff biological entity; and
ascertaining difference in rate of change from established averages of freshness and palatability which is indicative of contamination of said foodstuff biological entity.

2. A method according to claim 1, wherein:
said tracking step entails tracking episodically and/or serially changes associated with freshness, palatability and safety of said foodstuff biological entity.

3. A method according to claim 1, including the step of:
utilizing results of said subjecting step to illustrate an objective scale of palatability and freshness of said foodstuff biological entity.

4. A method according to claim 3, wherein:
said utilizing step also determines a value of an “Electrical Freshness”, “Palatability Index” or “eFRESH” certification for said foodstuff biological entity.

5. A method according to claim 1, including:
placing said foodstuff biological entity or a portion thereof in an electrical field; and
taking said measurements through a fixed or scanning process.

6. A method according to claim 1, wherein:
said bioelectrical impedance analysis includes measurement and/or calculation of resistance, reactance, impedance, capacitance, and/or phase angle of said foodstuff biological entity as determined through measurement by mono or multiple frequencies or spectroscopic analysis and by series and/or parallel circuit models; and
using voltage and current sufficient to accommodate the geometry of said foodstuff biological entity.

7. A method according to claim 1, including the steps of:
determining optimal aging, curing, and/or processing of said foodstuff biological entity; and
said subjecting step includes subjecting said foodstuff biological entity to bioelectrical impedance analysis for measurement, composition analysis, and serial tracking and grading of aging or preservation of said foodstuff biological entity and determination of aging or preservation (intentional or incidental) beyond palatability.

8. A method according to claim 1, including the step of:
comparing said measurements and calculations to normal values, average values, optimal values, and/or individual values, and in response to time and/or external influences purposeful or incidental.

9. A method according to claim 1, including the steps of:
determining palatability and freshness of a foodstuff biological entity, changes of palatability of said foodstuff biological entity, and/or timing of optimal palatability, loss of the palatability of said biological entity and/or illustrating an objective scale of palatability from which a producer, purveyor, merchant, preparer or consumer may objectively and subjectively apply individual tastes and select a preference from said scale;
providing normal, average, optimal and individual measured values of resistance, reactance, capacitance and phase angle, of a sample of said foodstuff biological entity;
measuring initial values of impedance, resistance, reactance, capacitance and phase angle of said sample;
taking measurements of impedance, resistance, reactance, capacitance and phase angle of said sample at predetermined intervals;
recording said measurements;
comparing initial values of said measurements to normal values of said measurements and to serially measured values of said measurements; and
determining, from said comparison steps, hallmarks of palatability of said foodstuff biological entity, said progression of changes in palatability and freshness of said biological entity, to a specific individual Palatability Index or Electrical Freshness value which may be reported and found as the inherent average, normal, optimal and/or safe individual characteristics of said foodstuff biological entity or portion thereof.

10. A method according to claim 9, including the steps of
determining a first value of a “Palatability/Freshness Index” from said measured initial values of impedance, resistance, reactance, capacitance and phase angle of said sample;
determining a second value of said “Palatability/Freshness Index” from said measurements at said predetermined intervals of time; and
determining third values of said “Palatability/Freshness Index” based upon said comparison steps.

11. The method of claim 1, including the step of:
utilizing results of said subjecting step to illustrate whether or not said foodstuff biological entity has been previously frozen or is fresh.

12. The method of claim 11, wherein;
said phase angle is used to indicate whether or not said foodstuff biological entity has been previously frozen or is fresh.

13. A method according to claim 1, including the steps of:
measuring and recording first values of impedance, resistance and reactance and calculating capacitance and phase angle of said foodstuff biological entity in an initial measurement;
placing said signal introduction and detection electrodes on/in or/around or within the superior and said inferior borders of said foodstuff biological entity;
placing said signal introduction and detection electrodes on/in or/around or within the opposite lateral borders of said foodstuff biological entity:
measuring and recording second values of said impedance, resistance and said reactance and calculating capacitance and phase angle of said of said biological entity;
comparing said first and/or second values to normal, average, optimal and individual values to determine if said foodstuff biological entity is palatable or not; and
performing serially additional series of said measurements and calculations repeated at predetermined intervals based upon individual characteristics of said foodstuff biological entity, the time it was harvested, and the manner it is stored and transported.

14. A method according to claim 13, including:
placing signal introduction and detection electrodes on/in or/around or within said foodstuff biological entity or a portion thereof, such as, on or within said opposite lateral peripheral borders of said foodstuff biological entity upon selecting or harvesting of said biological entity; and
placing signal introduction and detection electrodes on/in or/around or within said foodstuff biological entity at superior and inferior borders of said foodstuff biological entity or said portion thereof for a first part of said initial measurement upon said selection and harvesting of said foodstuff biological entity.

15. A method according to claim 13, including:
placing signal introduction and detection electrodes on, in or around or within said foodstuff biological entity or a portion thereof by placing said foodstuff biological entity or a portion thereof onto an electrode configuration comprised singularly or as part of an external appliance, such as, on or within the opposite lateral peripheral borders of said foodstuff biological entity or a portion thereof upon selecting or harvesting of said foodstuff biological entity; and
placing signal introduction and detection electrodes on, in or around or within said foodstuff biological entity or a portion thereof by placing said foodstuff biological entity or a portion thereof onto an electrode configuration singularly or as part of an external appliance at on, around or within the superior and inferior borders of said foodstuff biological entity or said portion thereof for a first part of said initial measurement upon said selection and harvesting of said foodstuff biological entity.

16. A method according to claim 1, including the step of:
using said phase angle as a safety and/or freshness indicator of said foodstuff biological entity.

17. A method according to claim 1, including the step of:
comparing a reactance value of one sample of the same genus and species, section and cut of a biological entity to another sample of the same genus and species, section and cut of a biological entity to illustrate a comparative scale of consumption safety.

18. A method of determining and monitoring the safety of a foodstuff biological entity including at least a portion of a live or previously-live organism, comprising the steps of:
subjecting said foodstuff biological entity to bioelectrical impedance analysis including measurement and/or calculation of values of resistance, reactance, impedance, capacitance, and/or phase angle of said foodstuff biological entity;
using said phase angle as a safety and/or freshness indicator of said foodstuff biological entity;
utilizing results of said subjecting step to illustrate an objective scale of palatability and freshness of said foodstuff biological entity;
tracking said values over time to illustrate freshness, palatability and safety of said foodstuff biological entity; and
ascertaining difference in rate of change from established averages of freshness and palatability which is indicative of contamination of said foodstuff biological entity.

19. A method of determining and monitoring the safety of a foodstuff biological entity including at least a portion of a live or previously-live organism, comprising the steps of:
subjecting said foodstuff biological entity to bioelectrical impedance analysis including measurement and/or calculation of values of resistance, reactance, impedance, capacitance, and/or phase angle of said foodstuff biological entity;
utilizing results of said subjecting step to illustrate an objective scale of palatability and freshness of said foodstuff biological entity;
said utilizing step also determines a value of an “Electrical Freshness”, “Palatability Index” or “eFRESH” certification for said foodstuff biological entity;
determining palatability and freshness of a foodstuff biological entity, changes of palatability of said foodstuff biological entity, and/or timing of optimal palatability, loss of the palatability of said biological entity and/or illustrating an objective scale of palatability from which a producer, purveyor, merchant, preparer or consumer may objectively and subjectively apply individual tastes and select a preference from said scale;
providing normal, average, optimal and individual measured values of resistance, reactance, capacitance and phase angle, of a sample of said foodstuff biological entity;
measuring initial values of impedance, resistance, reactance, capacitance and phase angle of said sample;
taking measurements of impedance, resistance, reactance, capacitance and phase angle of said sample at predetermined intervals;
recording said measurements;
comparing initial values of said measurements to normal values of said measurements and to serially measured values of said measurements; and
determining, from said comparison steps, hallmarks of palatability of said foodstuff biological entity, said progression of changes in palatability and freshness of said biological entity, to a specific individual Palatability Index or Electrical Freshness value which may be reported and found as the inherent average, normal, optimal and/or safe individual characteristics of said foodstuff biological entity or portion thereof.

20. A method according to claim 19, including the steps of
determining a first value of a “Palatability/Freshness Index” from said measured initial values of impedance, resistance, reactance, capacitance and phase angle of said sample;
determining a second value of said “Palatability/Freshness Index” from said measurements at said predetermined intervals of time; and
determining third values of said “Palatability/Freshness Index” based upon said comparison steps;
tracking said values over time to illustrate freshness, palatability and safety of said foodstuff biological entity; and
ascertaining difference in rate of change from established averages of freshness and palatability which is indicative of contamination of said foodstuff biological entity.
